(19) United States
(12) Patent Application Publication
(10) Pub. No.: US 2026/0083025 A1
(43) Pub. Date: Mar. 19, 2026

(54) Semiconductor Device and Method of Making a Peripheral Wall Structure in Fan-Out Redistribution Layers

(71) Applicant: STATS ChipPAC Pte. Ltd., Singapore (SG)

(72) Inventors: Swain Hong Alfred Yeo, Singapore (SG); Yi Xiang Jasper Tay, Singapore (SG); Jian Zuo, Singapore (SG); Linda Pei Ee Chua, Singapore (SG); Kai Chong Chan, Singapore (SG)

(73) Assignee: STATS ChipPAC Pte. Ltd., Singapore (SG)

(21) Appl. No.: 18/884,720

(22) Filed: Sep. 13, 2024

(51) Int. Cl. H01L 23/498; H01L 21/56; H01L 23/31

(52) U.S. Cl. CPC H10W 90/701; H10W 70/635; H10W 74/012; H10W 74/121; H10W 74/15

(57) ABSTRACT

A semiconductor device has a build-up interconnect structure. An opening is formed through the build-up interconnect structure. A peripheral wall structure is formed around the opening. A photonic semiconductor die is disposed over the build-up interconnect structure with a photonic circuit of the photonic semiconductor die aligned to the opening. A gap remains between the build-up interconnect structure and photonic semiconductor die over the peripheral wall structure. An underfill or encapsulant is deposited between the build-up interconnect structure and photonic semiconductor die.

### FIELD OF THE INVENTION

The present invention relates in general to semiconductor devices and, more particularly, to semiconductor devices and methods of making a peripheral wall structure in fan-out redistribution layers.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Photonic semiconductor devices, which are capable of transmitting or receiving signals via light, are becoming more and more common. Photonic semiconductor die are packaged with an optical window or grating area to allow optical signals in and out. When the package is molded or encapsulated, the encapsulation materials, such as molding compound, underfill, or mold underfill, can flow over the optical window or grating area, which can block the photonic circuit from properly sending or receiving optical signals. Therefore, a need exists for improved methods of keeping encapsulation materials from a grating surface or optical window of a photonic semiconductor die.

### BRIEF DESCRIPTION OF THE DRAWINGS

FIGS. 1a-1c illustrate a semiconductor wafer with a plurality of photonic semiconductor die separated by a saw street;

FIGS. 2a-2l illustrate forming a semiconductor package with the photonic semiconductor die and a peripheral wall structure;

FIGS. 3a-3d illustrate an alternative process flow;

FIGS. 4a-4e illustrate forming backside interconnect;

FIGS. 5a and 5b illustrate a heatsink embodiment;

FIG. 6 illustrates another embodiment;

FIGS. 7a and 7b illustrate a trench embodiment; and

FIGS. 8a and 8b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

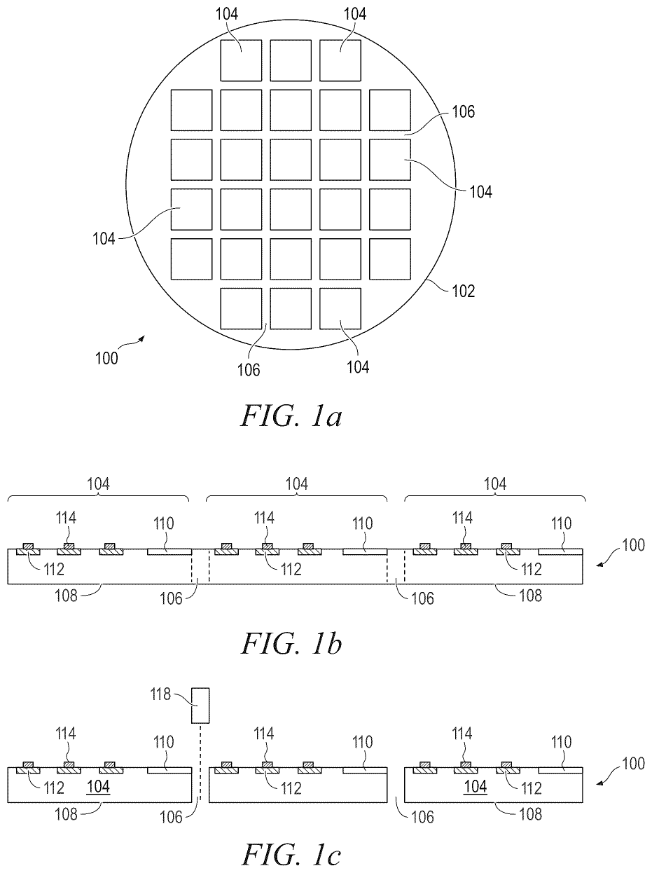

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of photonic semiconductor die 104 is formed on wafer 100 separated by a non-active, inter-die wafer area or saw street 106. Saw street 106 provides cutting areas to singulate semiconductor wafer 100 into individual photonic semiconductor die 104. In one embodiment, semiconductor wafer 100 has a width or diameter of 100-450 millimeters (mm). Wafer 100 can include hundreds or thousands of photonic semiconductor die 104. In some embodiments, photonic semiconductor die 104 is a silicon photonic die (PIC), photodetector, or a vertical-external-cavity surface-emitting-laser (VESCEL) component. Other types of photonic semiconductor die are used in other embodiments.

FIG. 1b shows a cross-sectional view of a portion of semiconductor wafer 100. Each photonic semiconductor die 104 has a back or non-active surface 108 and an active surface including a photonic circuit 110 formed within the die. Photonic circuit 110 is an electronic circuit capable of receiving an optical signal and converting the optical signal into an electrical signal for further processing, generate an optical signal based on a received electrical signal, or both. The area of, on, or over photonic circuit 110 may be referred to as a grating area because a grating connector is mounted there in some embodiments. The active surface may also include one or more transistors, diodes, and other circuit elements formed within the active surface to implement analog circuits or digital circuits, such as a digital signal processor (DSP), an application specific integrated circuit (ASIC), memory, or other signal processing circuit. Photonic semiconductor die 104 may also contain IPDs, such as inductors, capacitors, and resistors, for RF signal processing.

Wafer 100 is a wafer of photonic semiconductor die 104 as delivered by a manufacturer of the wafer to a manufacturer of semiconductor packages that will include the photonic semiconductor die. The manufacturer of wafer 100 has formed an interconnect structure over the active surface including contact pads 112 for external interconnect. The interconnect structure may have one or more layers of conductive traces with insulating layers formed between the layers. The interconnect structure also electrically interconnects photonic circuit 110 and contact pads 112 per the intended functionality of photonic semiconductor die 104.

The conductive layers, including contact pads 112, are formed over wafer 100 using physical vapor deposition (PVD), chemical vapor deposition (CVD), electrolytic plating, electroless plating, or another suitable metal deposition process. The conductive layers can be one or more layers of aluminum (Al), copper (Cu), tin (Sn), nickel (Ni), gold (Au), silver (Ag), or other suitable electrically conductive material. Any conductive layer mentioned above or below can be formed of the same methods and materials. Contact pads 112 include an under-bump metallization (UBM) in some embodiments.

Conductive microposts, microbumps, or micropillars 114 are formed on contact pads 112 of each semiconductor die 104 to provide external interconnection. Conductive micropillars 114 are typically formed by depositing conductive material into openings of a photolithographic mask layer and then removing the photolithographic mask layer. The material of micropillars 114 can be any of the materials mentioned herein for conductive layers, e.g., copper. In one embodiment, micropillars 114 have a copper core with a Ti/Cu plating 30 microns thick.

Micropillars 114 represent just one possible interconnect method. Other embodiments use bond wires, conductive paste, stud bumps, solder bumps, or any other suitable type of electrical interconnect. In some embodiments, an additional insulating or passivation layer is formed on the active surface around micropillars 114 with the micropillars extending above the insulating layer.

In FIG. 1c, semiconductor wafer 100 is singulated through saw street 106 using a saw blade or laser cutting tool 118 into individual photonic semiconductor die 104. The individual photonic semiconductor die 104 can be inspected and electrically tested for identification of known good die (KGD) or known good unit (KGU) after singulation.

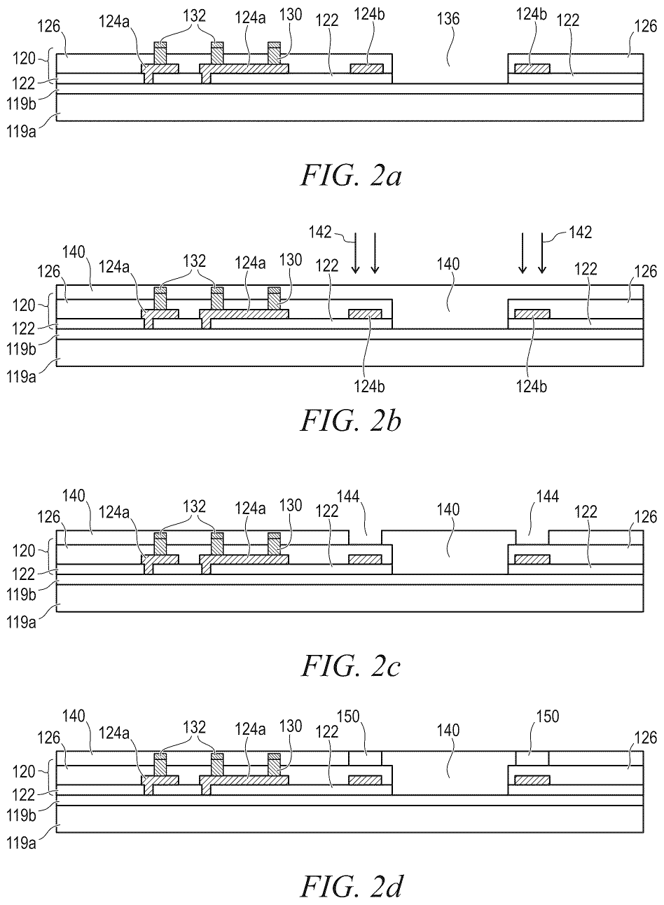

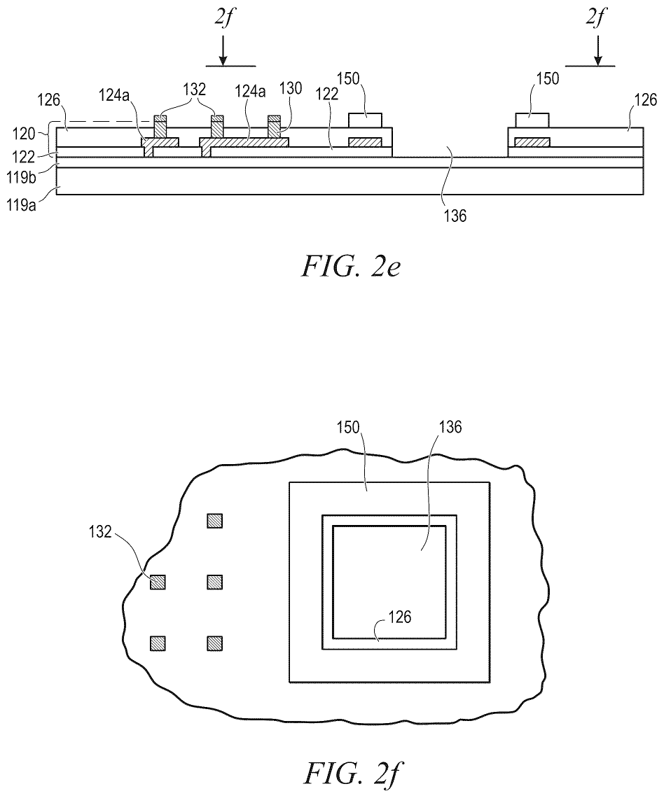

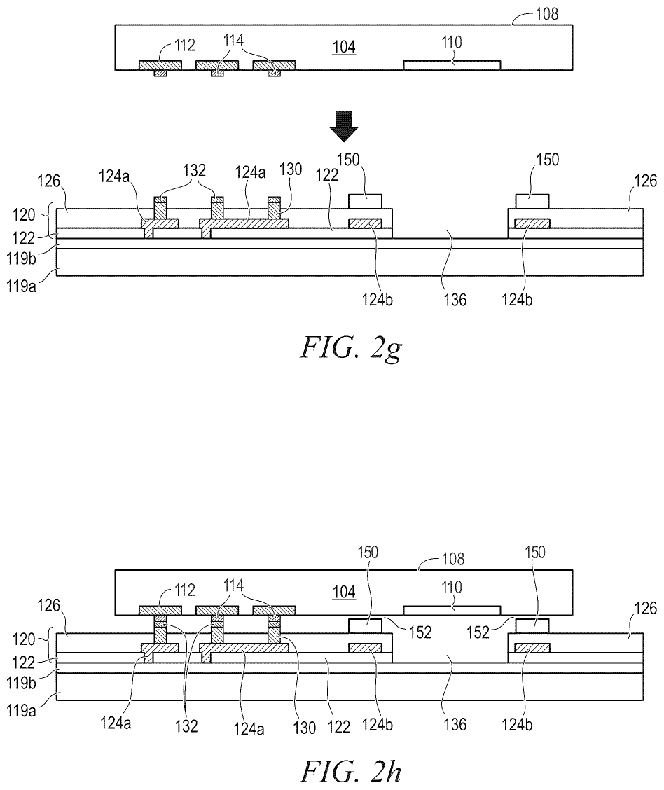

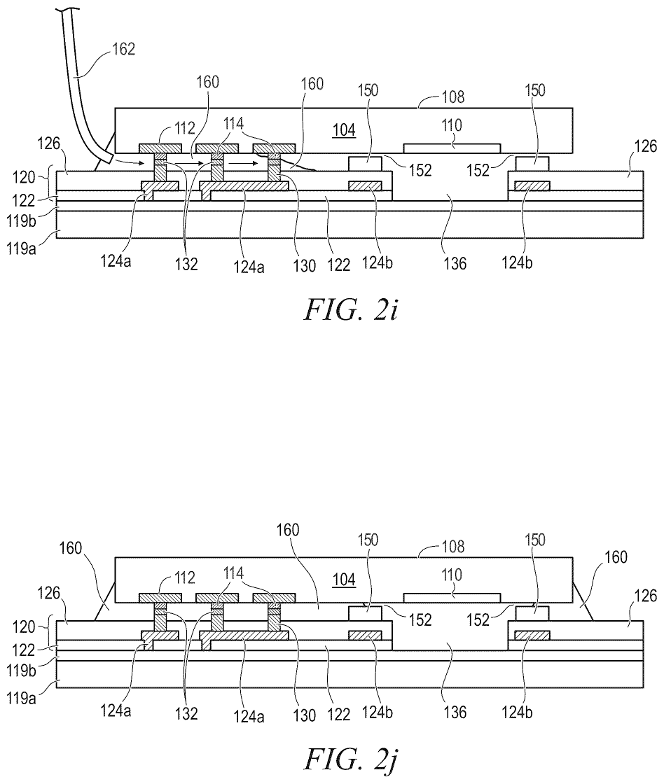

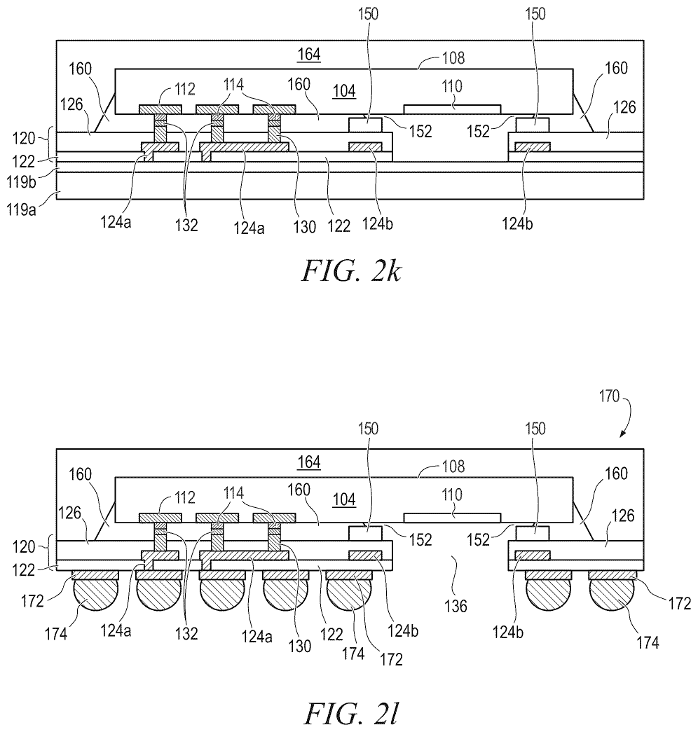

FIGS. 2a-2l illustrate the formation of an optical semiconductor package including a photonic semiconductor die 104. FIG. 2a shows a carrier 119a with an interface layer, debonding adhesive layer, or double-sided tape 119b optionally formed or disposed over carrier 119a as a temporary adhesive bonding film, etch-stop layer, thermal release layer, or UV release layer. Carrier 119a contains sacrificial base material such as silicon, polymer, beryllium oxide, glass, or other suitable low-cost, rigid material for structural support. The combination of carrier 119a and interface layer 119b is referred to as carrier 119.

A build-up interconnect structure 120 is formed on carrier 119. Interconnect structure 120 being called a build-up interconnect structure refers to the way that the interconnect structure is formed by successively building up insulating layers and conductive layers over carrier 119 until the desired signal routing is achieved.

Forming interconnect structure 120 starts by forming an insulating or passivation layer 122 on carrier 119.

Insulating layer 122 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 122 can be formed using PVD, CVD, printing, lamination, spin coating, spray coating, sintering, or thermal oxidation. Any insulating, passivation, or dielectric layer mentioned above or below can be formed using any of the materials or methods described for insulating layer 122.

Openings are formed through insulating layer 122 using chemical etching, photolithography, mechanical drilling, laser drilling, or another suitable process to expose the underlying carrier 119. A conductive layer 124 is formed over insulating layer 122 and includes conductive vias extending through the openings for subsequent vertical electrical interconnect. In other embodiments, conductive layer 124 is formed on insulating layer 122 without openings in the insulating layer. Openings can be formed later to expose contact pads of conductive layer 124 for electrical interconnect.

Conductive layer 124 is formed using any of the methods and materials described above for conductive layer 112. Any suitable conductive layer deposition and patterning method can be used in other embodiments, e.g., using an additive or subtractive process. Any conductive layer mentioned above or below can be formed as described for conductive layers 124 and 112. In some embodiments, conductive layer 124 is formed first on carrier 119 without passivation layer 122.

An insulating layer 126 is formed over passivation layer 122 and conductive layer 124 using methods and materials described above for passivation layer 122. Openings are formed through insulating layer 126 to expose contact pads or other portions of the underlying conductive layer 124. The openings can be formed by chemical etching, photolithography, mechanical drilling, laser drilling, or any other suitable means. Additional conductive layers and insulating layers can be interleaved over carrier 119 as needed to implement the desired electrical signal routing.

After the desired number of conductive layers and insulating layers have been built up, micropillars or other interconnect structures 130 are formed on the top conductive layer 124 through openings in the top insulating layer 126. Micropillars 130 are formed using any of the methods and materials as discussed above for conductive layer 124 or micropillars 114. Micropillars 130 are formed prior to insulating layer 126 in some embodiments. Micropillars 130 are formed directly on conductive layer 124 to physically and electrically contact the underlying conductive layer and extend vertically for electrical interconnect. Micropillars 130 include solder paste or solder caps 132 disposed on the tops of the micropillars using stencil printing or another suitable process.

An opening 136 is formed through interconnect structure 120 using chemical etching, mechanical drilling, laser ablation, or another suitable process. Opening 136 is formed after interconnect structure 120 is completed. In other embodiments, opening 136 is formed in each layer separately as the layers are formed along with the openings formed for conductive vias. Opening 136 is configured such that when photonic semiconductor die 104 is mounted to micropillars 130, photonic circuit 110 will be aligned to the opening. Opening 136 will then allow light signals to pass through interconnect structure 120 to photonic circuit 110.

Conductive layer 124 includes portions 124a comprised of conductive traces to fan-in or fan-out horizontally across the device footprint and, optionally, contact pads at ends of the traces for connecting to the underlying conductive vias and for subsequent formation of overlying conductive structures. Conductive layer 124 also includes portion 124b formed and patterned along with portions 124a, but physically separate from potions 124a, that forms a square or other-shaped ring around opening 136. Portion 124b has a similar or identical footprint to peripheral wall structure 150, discussed below and illustrated in FIG. 2f.

FIGS. 2b-2f show the formation of peripheral wall structure 150 on interconnect structure 120 in one embodiment. In FIG. 2b, a photoresist layer 140 is deposited over interconnect structure 120. Light 142 is used to weaken photoresist layer 140 where peripheral wall structure 150 is desired. Light 142 is masked elsewhere so that, when the photoresist layer is developed, an opening 144 is formed through the photoresist layer in the desired shape for the peripheral wall structure as shown in FIG. 2c.

Opening 144 extends in a complete circuit around opening 136 so that, when the openings are filled with deposited insulating material as shown in FIG. 2d, the insulating material forms a peripheral wall structure 150 in the desired shape extending completely around opening 136. Photoresist layer 140 is removed in FIGS. 2e and 2f to leave peripheral wall structure 150 sitting on insulating layer 126 over conductive layer portion 124b. Peripheral wall structure 150 can be formed using any of the materials and methods discussed above for insulating layer 122. In one embodiment, insulating layer 122, insulating layer 126, and peripheral wall structure 150 are all formed of polyimide.

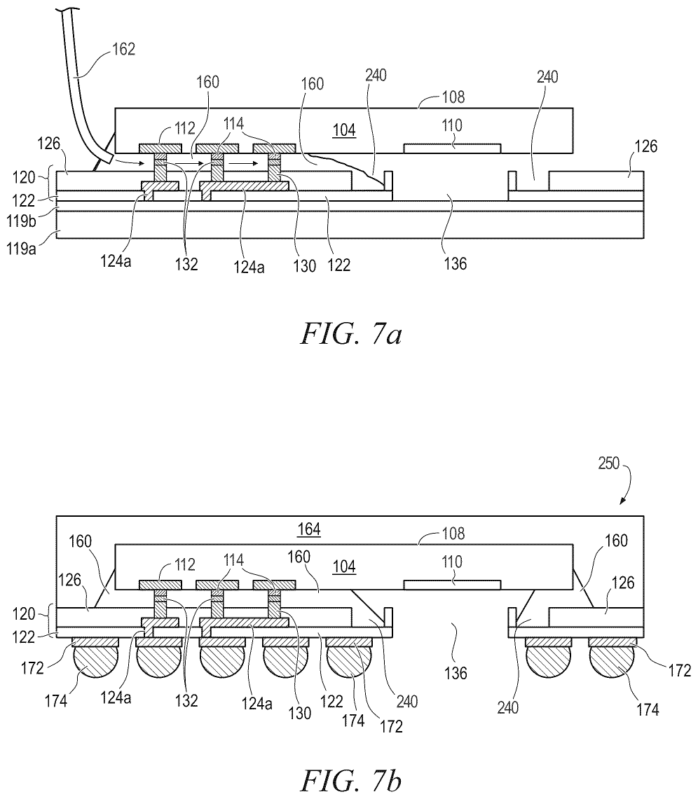

In another embodiment, photoresist layer 140 is a negative photoresist. Light 142 in FIG. 2b solidifies photoresist layer 140 where peripheral wall structure 150 is desired. Upon development, the remainder of photoresist layer 140 is washed away leaving just peripheral wall structure 150, which was the portion of photoresist layer 140 exposed to light 142. In the negative photoresist embodiment, the process flow goes directly from FIG. 2b to FIGS. 2e and 2f as development removes the portions of photoresist layer 140 where light 142 is masked. As an alternative to forming peripheral wall structure 150 over interconnect structure 120, a trench can be formed into insulating layer 126 as shown in FIGS. 7a and 7b. Without conductive layer portion 124b, the trench can extend all the way through insulating layer 126 to expose the underlying insulating layer 122. Alternatively, the trench can extend completely through interconnect structure 120 or conductive layer portion 124b can be used as an etch stop layer.

FIG. 2e shows a cross-sectional view of peripheral wall structure 150 on interconnect structure 120 while FIG. 2f shows a plan view. A height of peripheral wall structure 150 over interconnect structure 120 is between 10μm and 50μm in some embodiments. In plan view, peripheral wall structure 150 completely and continuously surrounds opening 136. Peripheral wall structure 150 has the same or a similar shape to opening 136, but is larger so that the opening fits within the peripheral wall structure. For instance, both opening 136 and peripheral wall 150 are square in the illustrated embodiment, but both could be circular, hexagonal, oblong, or any other suitable shape. It is not technically necessary for the shapes of peripheral wall structure 150 and opening 136 to match, but that is typically the most efficient use of device real estate. Having conductive layer portion 124b directly under peripheral wall structure 150, and matching the footprint thereof, is optional and enhances the structure or height of the peripheral wall structure.

In FIG. 2g, a photonic semiconductor die 104 is picked and placed over interconnect structure 120. Each micropillar 114 from photonic semiconductor die 104 is aligned to a respective micropillar 130 on interconnect structure 120 so that, when the photonic semiconductor die is lowered onto the interconnect structure in FIG. 2h, the micropillars are electrically and physically connected to each other by reflowing solder caps 132 between the respective micropillars. A gap 152 remains between the top of peripheral wall structure 150 and the active surface of photonic semiconductor die 104. Gap 152 ensures that contact between photonic semiconductor die 104 and peripheral wall structure 150 does not induce damage to the corresponding dielectric layers during the flip-chip assembly process or interfere in the solder interconnection of micropillars 130 and 114. In other embodiments, photonic semiconductor die 104 rests on peripheral wall structure 150.

In FIG. 2i, an underfill 160 is deposited between interconnect structure 120 and photonic semiconductor die 104 using a dispenser head or nozzle 162. Other underfill deposition methods are used in other embodiments. Underfill 160 flows into the space between interconnect structure 120 and photonic semiconductor die 104 to fill the space and provide physical support. Underfill 160 can be a polymer composite material, such as epoxy resin or epoxy acrylate, with or without an added filler. In one embodiment, gap 152 is configured to have a height that is less than a size of filler used in underfill 160 so that the filler does not physically fit through gap 152 to reach opening 136. For instance, a filler of 10μm is used in one embodiment, and gap 152 has a height of less than 10μm. Filler size refers to the average or minimum physical dimension of the individual pieces of filler disposed in the underfill.

Blocking the filler of underfill 160 will ensure that almost none of the underfill makes it through gap 152 into opening 136, which would block desired light through the opening. Even without a filler, or with a filler that is smaller than gap 152, the small gap slows the flow of underfill 160 sufficiently that there is little chance of any of the underfill reaching into opening 136 over photonic circuit 110. Nozzle 162 is moved around photonic die 104 in one embodiment to ensure that the space between the photonic semiconductor die and interconnect structure 120 is completely filled all the way around peripheral wall structure 150. Opening 136 remains free of underfill 160 due to blocking of the underfill by peripheral wall structure 150. In embodiments where a trench is formed into insulating layer 126 instead of peripheral wall structure 150 being formed on the insulating layer, any underfill 160 that would have otherwise flowed into opening 136 will be captured by the trench. In any embodiment, when deposition of underfill 160 is completed in FIG. 2j, the underfill does not extend into opening 136 or over photonic circuit 110.

In FIG. 2k, an encapsulant or molding compound 164 is deposited over and around photonic semiconductor die 104 and interconnect structure 120 using a paste printing, compression molding, transfer molding, liquid encapsulant molding, vacuum lamination, spin coating, or other suitable applicator. Encapsulant 164 can be liquid or granular polymer composite material, such as epoxy resin, epoxy acrylate, or another suitable polymer, with or without a filler. Encapsulant 164 is non-conductive, provides structural support, and environmentally protects the semiconductor device from external elements and contaminants. In some embodiments, underfill 160 is not used, and peripheral wall structure 150 still provides the same benefits, mentioned above for the underfill, by blocking encapsulant 164 from flowing over photonic circuit 110. Without underfill 160, FIG. 2k would look the same except for the two outer lines defining the area of underfill 160 would be removed, while the lines defining the inner boundary of the underfill between peripheral wall structure 150 and photonic semiconductor die 104 would be the inner boundary of encapsulant 164 instead.

FIG. 2l illustrates carrier 119 removed by thermal, UV, or other release. A semiconductor package 170 is completed by adding any necessary structures for external interconnect, e.g., UBM or contact pads 172 and solder bumps 174, and singulating encapsulant 164 and interconnect structure 120 if necessary to separate a panel of packages from each other. Contact pads 172 are formed as a conductive layer on the surface of interconnect structure 120 and patterned using the methods and materials described above for other conductive layers. The conductive layer may include conductive traces to fan-out or fan-in electrical connections from conductive layer 124, or only have contact pads formed on exposed conductive vias of conductive layer 124. In some embodiments, conductive layer 124 has no vias extending through insulating layer 122, in which case openings are formed through insulating layer 122 prior to forming UBM or contact pads 172 or forming solder bumps 174 directly on conductive layer 124.

To form solder bumps 174, an electrically conductive bump material is deposited over contact pads 172 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads 172 using a suitable attachment or bonding process. In one embodiment, the bump material is reflowed by heating the material above its melting point to form balls or bumps 174. Contact pads 172 can be, or include, an under-bump metallization (UBM) having a wetting layer, barrier layer, and adhesion layer. Bumps 174 can also be compression bonded or thermocompression bonded to conductive layer 172.

Bump 174 represents one type of interconnect structure that can be formed over conductive layer 172. The interconnect structure can also use bond wires, conductive paste, stud bump, micro bump, or other electrical interconnect. In one embodiment, contact pads 172 are left exposed without bumps 174 so that package 170 can be mounted with the opposite surface of encapsulant 164 attached onto a PCB or other substrate of a larger electronic device, and then contact pads 172 can be connected to the substrate by bond wires. That embodiment allows opening 136 to be oriented away from the electronic device substrate that the package is mounted onto so that a fiber optic cable can more easily be connected.

In some embodiments, a fiber optic connector is mounted in opening 136 as part of the packaging process. In other embodiments, opening 136 remains open as illustrated and a fiber optic connector or bare fiber is glued into opening 136 as part of the process of installing package 170 into an end device. Alternatively, a lens can be glued into opening 136 during packaging or later.

Package 170 includes a photonic semiconductor die 104 with a photonic circuit 110 that remains free of interference from underfill 160 or encapsulant 164 thanks to peripheral wall structure 150. Peripheral wall structure 150 protects the optical window or grating surface of photonic semiconductor die 104. Peripheral wall structure 150 defines a keep-out zone (KOZ) for underfill or encapsulant, extending around opening 136 and photonic circuit 110 to keep encapsulant or underfill from interfering with light transmission. Peripheral wall structure 150 can be formed using the same methods and materials as the underlying insulating layers of interconnect structure 120, so no new materials are required.

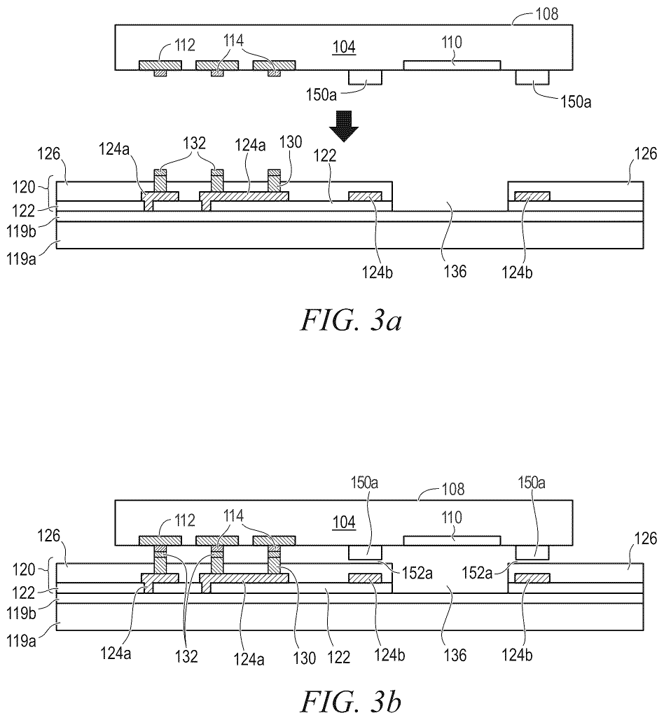

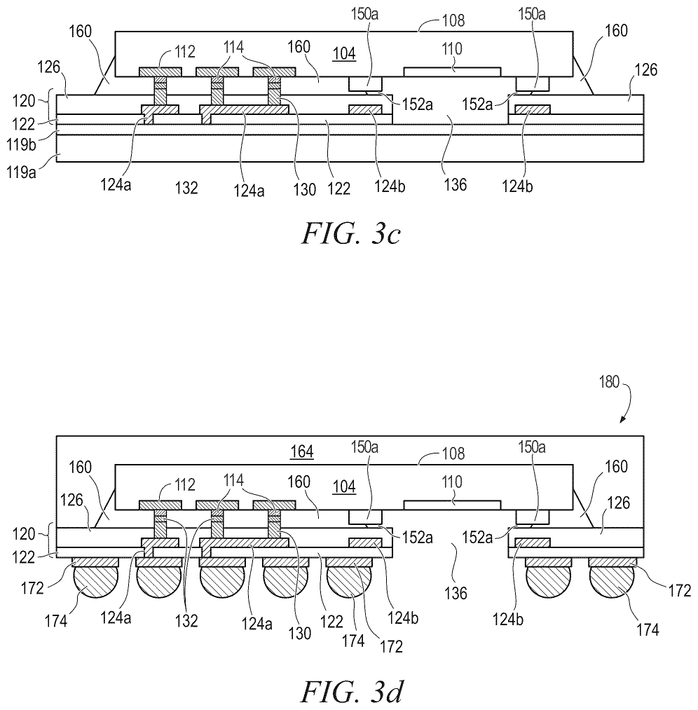

FIGS. 3a-3d illustrate an embodiment with peripheral wall structure 150a formed on photonic semiconductor die 104 instead of on interconnect structure 120 as with peripheral wall structure 150. Peripheral wall structure 150a is formed using any of the methods and materials described above for peripheral wall structure 150. Photonic semiconductor die 104 with peripheral wall structure 150a is picked and placed over interconnect structure 120 in FIG. 3a.

FIG. 3b shows photonic semiconductor die 104 mounted on interconnect structure 120 with solder caps 132 having been reflowed between micropillars 130 and 114 to physically attach and electrically connect the photonic semiconductor die and interconnect structure. A gap 152a optionally remains between peripheral wall structure 150a and interconnect structure 120 for the same reasons discussed above for gap 152. As with the previous embodiment, peripheral wall structure 150a surrounds opening 136 as a complete circuit in plan view to block underfill 160 or encapsulant 164.

FIG. 3c shows underfill 160 having been deposited without flowing into opening 136 thanks to peripheral wall structure 150a. Package 180 is complete in FIG. 3d by depositing encapsulant 164, forming contact pads 172 and bumps 174 or another interconnect structure, and singulating if necessary.

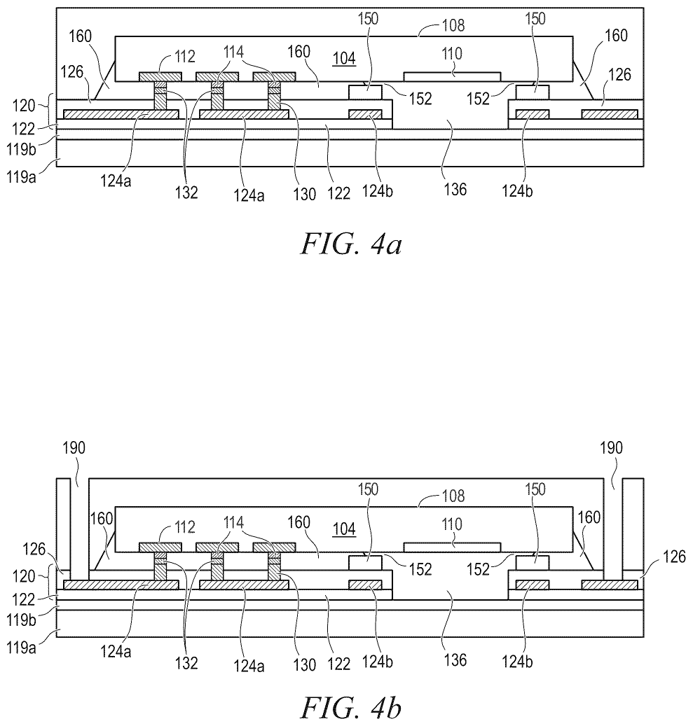

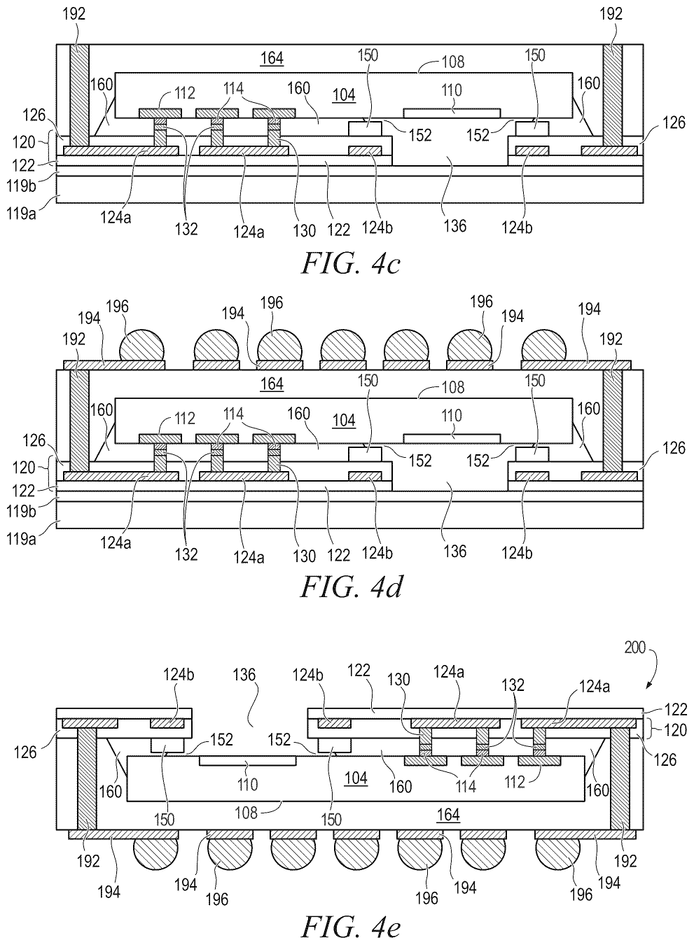

FIGS. 4a-4e illustrate an embodiment with backside external interconnect. FIG. 4a continues from FIG. 2k, with the addition of conductive layer portions 124a that now extend out toward the edges of interconnect structure 120, outside of the footprint of photonic semiconductor die 104. In FIG. 4b openings or vias 190 are formed through encapsulant 164 and insulating layer 126 down to conductive layer 124. Vias 190 are formed by chemical etching, laser etching, mechanical drilling, or another suitable means. Vias 190 expose conductive layer 124 for subsequent electrical interconnect.

In FIG. 4c, vias 190 are filled with conductive material to form conductive vias 192. Conductive vias 192 are formed by any suitable conductive material deposition means, such as those discussed above for other conductive layers. Conductive vias 192 can be formed of any suitable conductive material, such as those discussed above for conductive layers generally, e.g., copper. Top surfaces of conductive vias 192 are made coplanar to the top surface of encapsulant 164 by backgrinding in some embodiments.

In FIG. 4d, conductive layer 194 and solder bumps 196 are formed on the back surface of encapsulant 164. Conductive layer 194 is formed using methods and materials mentioned above for other conductive layers, and is patterned to fan-in electrical connection from conductive vias 192 to solder bumps 196. Bumps 196 are formed on contact pads of conductive layer 194 using the same methods and materials discussed above for solder bumps 174.

In FIG. 4e, semiconductor package 200 is completed by removing carrier 119 to expose interconnect structure 120 and photonic circuit 110 through opening 136, and singulating if necessary. Forming bumps 196 on the back surface of encapsulant 164 instead of on interconnect structure 120 allows normal flip-chip mounting with bumps 196 to leave photonic circuit 110 exposed in a direction oriented opposite the underlying device substrate, which is more convenient in many use-cases.

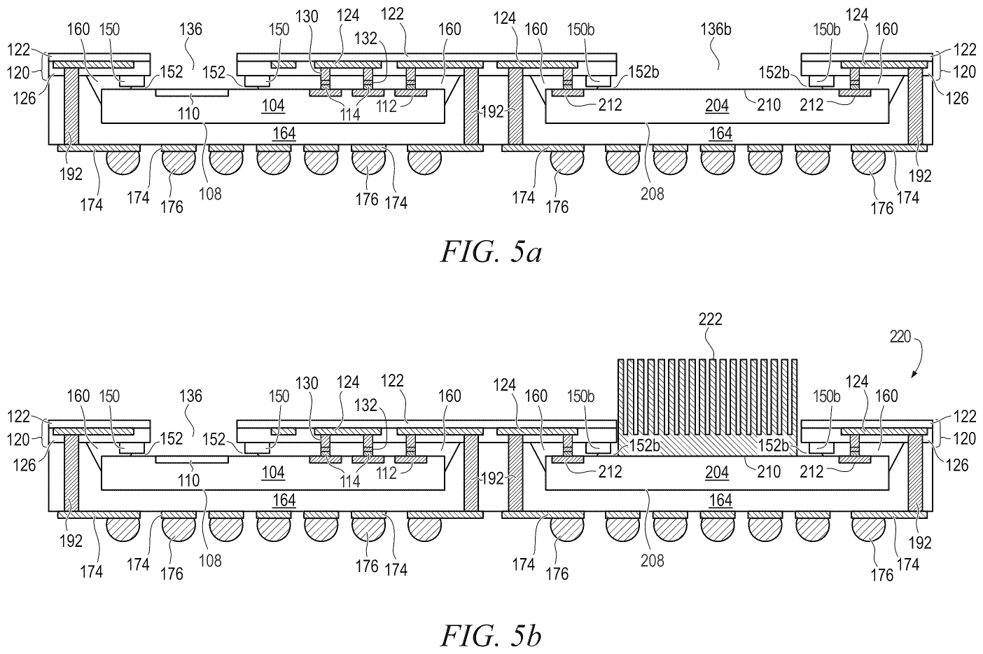

The same general concept of peripheral wall structure 150 can be used when leaving a semiconductor die or other electrical component exposed for nearly any reason. As just one additional example, FIGS. 5a and 5b show forming a semiconductor package 220 with a peripheral wall structure 150b used with an exposed semiconductor die 204 to allow a heatsink 222 to be attached to the semiconductor die. FIG. 5a shows a nearly completed package with interconnect structure 120 extended out to fit the mounting of both photonic semiconductor die 104 and also a normal semiconductor die 204. Semiconductor die 204 is formed from a wafer in a similar manner to photonic semiconductor die 104 but does not include a photonic circuit. Rather, semiconductor die 204 has an active surface 210 with contact pads 212 for electrical interconnect.

A second opening 136b is formed in interconnect structure 120 to accommodate exposing active surface 210 of semiconductor die 204. Peripheral wall structure 150b is formed on interconnect structure 120 around opening 136b during the same processing steps as the first peripheral wall structure 150 is formed around opening 136. Peripheral wall structure 150b blocks underfill 160 from flowing into opening 136b in the same way as described above for peripheral wall structure 150. A gap 152b is optionally left between peripheral wall structure 150b and semiconductor die 204 for the same benefits as described above for gap 152.

In FIG. 5b a heatsink 222 is mounted onto active surface 210 of semiconductor die 204 through opening 136b. Heatsink 222 can be soldered onto active surface 210, attached using a thermally conductive adhesive, or by any other suitable means. In some embodiment, surface 208 is the active surface of semiconductor die 204, rather than the exposed surface, and connected to contact pads 212 by through-silicon vias in the semiconductor die. Opening 136b can be used to expose a surface of any semiconductor die or other electrical component for any purpose, with or without being co-packaged with a photonic semiconductor die 104.

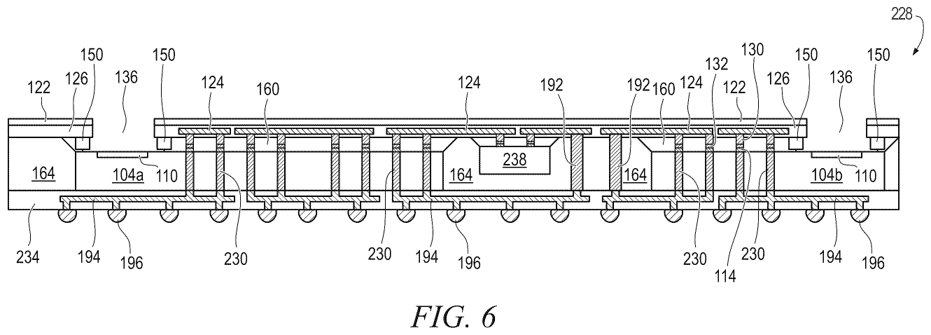

FIG. 6 illustrates another more complex embodiment with two photonic semiconductor die 104a and 104b in the same semiconductor package 228. A separate opening 136 and peripheral wall structure 150 is formed for the photonic circuit 110 of each photonic semiconductor die 104. Package 228 uses conductive vias 192 for vertical interconnect as in semiconductor package 200 above. In addition, through-silicon vias 230 are formed through photonic semiconductor die 104a and 104b to provide additional vertical interconnect. Conductive vias 230 can be used without conductive vias 192, and with only a single photonic semiconductor die in other embodiments. Conductive layer 194 is formed as part of a build-up interconnect structure interleaved with one or more insulating layers 234 and additional conductive layers if desired.

Additional electrical components 238 are disposed on interconnect structure 120 along with photonic semiconductor die 104a and 104b. Any desired electrical components to implement the electrical functionality of the semiconductor package being formed are mounted on interconnect structure 120 in all of the above embodiments. Additional electrical components 238 can be discrete electrical devices, such as diodes, transistors, resistors, capacitors, or inductors. Electrical components 238 can include other semiconductor die, semiconductor packages, surface mount devices, RF components, discrete electrical devices, and may include integrated passive devices (IPDs).

FIGS. 7a and 7b illustrate an embodiment utilizing a trench 240 instead of peripheral wall structure 150. FIG. 7a illustrates trench 240 formed through insulating layer 126. Trench 240 can be formed only partially through insulating layer 126, or extend completely through insulating layer 126 and partially through insulating layer 122. Trench 240 extends in a complete circuit around opening 136 as with the plan view of peripheral wall structure 150 in FIG. 2f. As underfill 160 is deposited, the underfill flows into trench 240 prior to reaching opening 136. The size of trench 240 is sufficient to capture any excess underfill. FIG. 7b illustrates a completed package 250 with trench 240. Opening 136 remains free of underfill 160 because trench 240 captured the underfill prior to the underfill flowing into the main opening. Trench 240 can be used instead of peripheral wall structure 240 in any of the above embodiments.

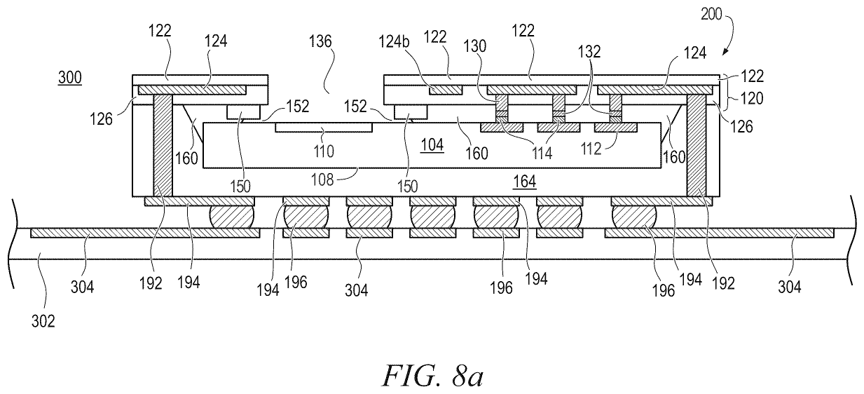

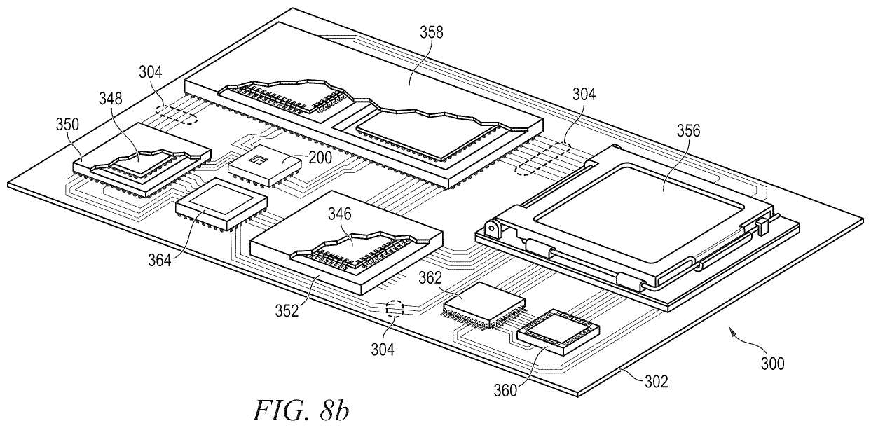

FIGS. 8a and 8b illustrate integrating the above-described semiconductor packages, e.g., semiconductor package 200, into a larger electronic device 300. FIG. 8a illustrates a partial cross-section of semiconductor package 200 mounted onto a printed circuit board (PCB) or other substrate 302 as part of electronic device 300. Solder bumps 196 are reflowed onto conductive layer 304 of PCB 302 to physically attach and electrically connect semiconductor package 200 to the PCB. In other embodiments, thermocompression or another suitable attachment and connection methods are used. In some embodiments, an adhesive or underfill layer is used between semiconductor package 200 and PCB 302. Photonic semiconductor die 104 is electrically coupled to conductive layer 304 through bumps 196, conductive layer 194, conductive vias 192, conductive layer 124, micropillars 130, solder 132, and micropillars 114.

FIG. 8b illustrates electronic device 300 having a chip carrier substrate or PCB 302 with a plurality of semiconductor packages disposed on a surface of PCB 302, including semiconductor package 200. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 8b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
forming a build-up interconnect structure;
forming an opening through the build-up interconnect structure;
forming a peripheral wall structure around the opening;
disposing a photonic semiconductor die over the build-up interconnect structure with a photonic circuit of the photonic semiconductor die aligned to the opening, wherein a gap remains between the build-up interconnect structure and photonic semiconductor die over the peripheral wall structure; and
depositing an underfill or encapsulant between the build-up interconnect structure and photonic semiconductor die.

2. The method of claim 1, wherein the underfill or encapsulant includes a filler having a size greater than the gap.

3. The method of claim 1, further including:
forming the peripheral wall structure on the build-up interconnect structure; and
forming the build-up interconnect structure to include a portion of a conductive layer under the peripheral wall structure.

4. The method of claim 1, further including depositing a second encapsulant over the photonic semiconductor die after depositing the underfill or encapsulant.

5. The method of claim 1, further including forming a conductive layer over the photonic semiconductor die opposite the build-up interconnect structure.

6. The method of claim 5, further including forming a conductive via extending between the build-up interconnect structure and conductive layer.

7. A method of making a semiconductor device, comprising:
forming a build-up interconnect structure;
forming an opening through the build-up interconnect structure;
forming a peripheral wall structure around the opening;
disposing a semiconductor die over the opening; and
depositing an underfill or encapsulant between the build-up interconnect structure and semiconductor die.

8. The method of claim 7, further including disposing a heatsink on the semiconductor die in the opening.

9. The method of claim 7, further including forming the peripheral wall structure on the build-up interconnect structure.

10. The method of claim 9, further including forming the build-up interconnect structure to include a portion of a conductive layer under the peripheral wall structure.

11. The method of claim 7, further including depositing a second encapsulant over the semiconductor die after depositing the underfill or encapsulant.

12. The method of claim 7, further including forming a conductive layer over the semiconductor die opposite the build-up interconnect structure.

13. The method of claim 12, further including forming a conductive via extending between the build-up interconnect structure and conductive layer.

14. A semiconductor device, comprising:
a build-up interconnect structure;
an opening formed through the build-up interconnect structure;
a peripheral wall structure extending around the opening;
a photonic semiconductor die disposed over the build-up interconnect structure with a photonic circuit of the photonic semiconductor die aligned to the opening; and
an underfill or encapsulant deposited between the build-up interconnect structure and photonic semiconductor die.

15. The semiconductor device of claim 14, wherein the peripheral wall structure is formed on the build-up interconnect structure.

16. The semiconductor device of claim 15, wherein the build-up interconnect structure includes a portion of a conductive layer under the peripheral wall structure.

17. The semiconductor device of claim 14, further including a second encapsulant deposited over the photonic semiconductor die opposite the underfill or encapsulant.

18. The semiconductor device of claim 14, further including a conductive layer formed over the photonic semiconductor die opposite the build-up interconnect structure.

19. The semiconductor device of claim 18, further including a conductive via extending between the build-up interconnect structure and conductive layer.

20. A semiconductor device, comprising:
a build-up interconnect structure;
an opening formed through the build-up interconnect structure;
a peripheral wall structure extending around the opening;
a semiconductor die disposed over the opening; and
an underfill or encapsulant disposed between the build-up interconnect structure and semiconductor die.

21. The semiconductor device of claim 20, further including a heatsink disposed on the semiconductor die in the opening.

22. The semiconductor device of claim 20, wherein the peripheral wall structure is formed on the build-up interconnect structure.

23. The semiconductor device of claim 22, wherein the build-up interconnect structure includes a portion of a conductive layer under the peripheral wall structure.

24. The semiconductor device of claim 20, further including a second encapsulant deposited over the semiconductor die opposite the underfill or encapsulant.

25. The semiconductor device of claim 20, further including:
a conductive layer formed over the semiconductor die opposite the build-up interconnect structure; and
a conductive via extending between the build-up interconnect structure and conductive layer.
